(19) United States
(12) Patent Application Publication
(10) Pub. No.: US 2026/0050701 A1
(43) Pub. Date: Feb. 19, 2026

(54) FIXTURE IMPLEMENTATION SYSTEM AND METHOD

(71) Applicant: M3 Innovation, LLC, Syracuse, NY (US)

(72) Inventors: Christopher D. Nolan, Camillus, NY (US); Joseph R. Casper, Baldwinsville, NY (US)

(73) Assignee: M3 Innovation, LLC, Syracuse, NY (US)

(21) Appl. No.: 19/068,755

(22) Filed: Mar. 3, 2025

Related U.S. Application Data
(60) Provisional application No. 63/560,577, filed on Mar. 1, 2024.

(51) Int. Cl. G06F 30/13; F21S 8/08

(52) U.S. Cl. CPC G06F 30/13; F21S 8/085

(57) ABSTRACT

In one aspect of the present disclosure provided herein, is a lighting layout system for executing instructions comprising: receiving an input layout having a project identifier, field information, field luminosity information; a field layout associated with the field information; processing the input layout using the processor; creating an output having a field type, the quantity of poles and pole locations, a pole label, a fixture count per pole, a total fixture count per type, a total wattage, an achieved average light level and uniformity result, a point-by-point overlay of the field, an aiming diagram showing the aiming point on the field for each pole, and a rack diagram showing each fixture and its aiming for each pole; and displaying the output by the output device.

This application claims priority under 35 U.S.C. § 119 to U.S. Provisional Application No. 63/560,577, filed Mar. 1, 2024, which is herein incorporated by reference in its entirety.

### BACKGROUND OF THE INVENTION

### Technical Field

The present invention relates to devices, systems, and method for photometric design for lighting fixture implementation and, more specifically, for devices, systems, software, and method for photometric design for lighting fixture implementation in large illumination projects such as sports field and stadium lighting systems including illuminations systems employing asymmetric illumination sources.

### Background Information

At sports fields and stadiums, lighting systems are employed to allow sports and other events to continue after sunset or indoors. Determining the placement of support poles and then optimizing fixture placement and positioning to achieve desired lighting position is currently time consuming and require a considerable amount of trial and error, resulting in an expensive process. Often, support posts are positioned around a field and another party is tasked with implementing and positioning the lighting system. Creating submittal packages for projects that contain point-by-point calculations is a tedious task that requires specialized skill and high costs. Even after the submittal package is made, additional adjustments may be required. Thus, a more efficient system is needed.

### SUMMARY OF THE INVENTION

The present disclosure is directed toward systems, methods, and devices, providing fixture implementation systems and methods.

In one aspect of the present disclosure provided herein, is a method for executing instructions in a lighting layout system including: receiving an input layout having a project identifier, field information, field luminosity information; a field layout associated with the field information; processing the input layout using the processor; creating an output having a field type, the quantity of poles and pole locations, a pole label, a fixture count per pole, a total fixture count per type, a total wattage, an achieved average light level and uniformity result, a point-by-point overlay of the field, an aiming diagram showing the aiming point on the field for each pole, and a rack diagram showing each fixture and its aiming for each pole; and displaying the output by the output device. The project identifier includes a project name, a location, and client information. The field information includes at least one field image, a field type, a background image, a size, and a calculation grid. The field layout associated with the field information, includes a quantity of poles, pole locations, a fixture mounting height, a fixture type, a quantity of fixtures, and aiming information. The point-by-point overlay of the field includes the pole locations indicated, the fixture schedule, and a results summary for each layout.

In one aspect of the present disclosure provided herein, is a method for light fixture implementation including: receiving a map and luminosity information, creating spill lines; overlaying a coordinate grid on a map, generate light pole locations on the map, creating light pole height and light intensity results, generating circuit breaker sizing, generating a bill of materials, generating light pole installation instructions, and providing proposal pricing.

In one aspect of the present disclosure provided herein, is a lighting layout system for executing instructions comprising: receiving an input layout having a project identifier, field information, field luminosity information; a field layout associated with the field information; processing the input layout using the processor; creating an output having a field type, the quantity of poles and pole locations, a pole label, a fixture count per pole, a total fixture count per type, a total wattage, an achieved average light level and uniformity result, a point-by-point overlay of the field, an aiming diagram showing the aiming point on the field for each pole, and a rack diagram showing each fixture and its aiming for each pole; and displaying the output by the output device. The project identifier includes a project name, a location, and client information. The field information includes at least one field image, a field type, a background image, a size, and a calculation grid. The field layout associated with the field information, includes a quantity of poles, pole locations, a fixture mounting height, a fixture type, a quantity of fixtures, and aiming information. The point-by-point overlay of the field includes the pole locations indicated, the fixture schedule, and a results summary for each layout.

These, and other objects, features and advantages of this invention will become apparent from the following detailed description of the various aspects of the invention taken in conjunction with the accompanying drawings.

### BRIEF DESCRIPTION OF THE DRAWINGS

The present invention will be more fully understood and appreciated by reading the following Detailed Description in conjunction with the accompanying drawings, in which:

FIG. 1 is a perspective view of an asymmetric source sports lighting system in accordance with an aspect of the present invention;

FIG. 2 is a perspective view of the upper portion of a support pole of an asymmetric source sports lighting system in accordance with an aspect of the present invention;

FIG. 3 is a perspective view of the asymmetric lighting source for a lighting module in accordance with an aspect of the present invention;

FIG. 4 is a mechanical view of the light emitting diode (LED) layout for an asymmetric lighting source in accordance with an aspect of the present invention;

FIG. 5 is schematic of the electronics for an asymmetric lighting source in accordance with an aspect of the present invention;

FIG. 6 is a perspective view of a lighting module in accordance with an aspect of the present invention having a lens array thereon;

FIG. 7 is a perspective view of the male and female couplers of a lighting module in accordance with an aspect of the present invention;

FIG. 8 is a cross-sectional view of the male and female couplers of a lighting module in accordance with an aspect of the present invention;

FIG. 9 is a perspective view of a coupler clamp for securing lighting modules to each other in accordance with an aspect of the present invention

FIG. 10 is cross-sectional view of a lighting module to lighting module connection in accordance with an aspect of the present invention;

FIG. 11 is an electrical diagram of a lighting module to lighting module connection in accordance with an aspect of the present invention;

FIG. 12 is two perspective views of a mount in accordance with an aspect of the present invention;

FIG. 13 is an electrical diagram of a lighting module to mount connection in accordance with an aspect of the present invention;

FIG. 14 is a perspective view showing axial rotation of a series of interconnected lighting modules in accordance with an aspect of the present invention;

FIG. 15 is a perspective view of a controller stack in accordance with an aspect of the present invention;

FIG. 16 is a perspective view of a core enclosure in accordance with an aspect of the present invention;

FIG. 17 is high level schematic for a lighting system in accordance with an aspect of the present invention;

FIG. 18 is a detailed schematic of a master controller in accordance with an aspect of the present invention;

FIG. 19 is a detailed schematic of a core enclosure in accordance with an aspect of the present invention

FIG. 20 is a schematic of wireless monitoring and control approach in accordance with an aspect of the present invention; and

FIG. 21 is a schematic of beam steering using a lighting system in accordance with an aspect of the present invention;

FIG. 22 is a schematic of beam angles changes using a lighting system in accordance with an aspect of the present invention;

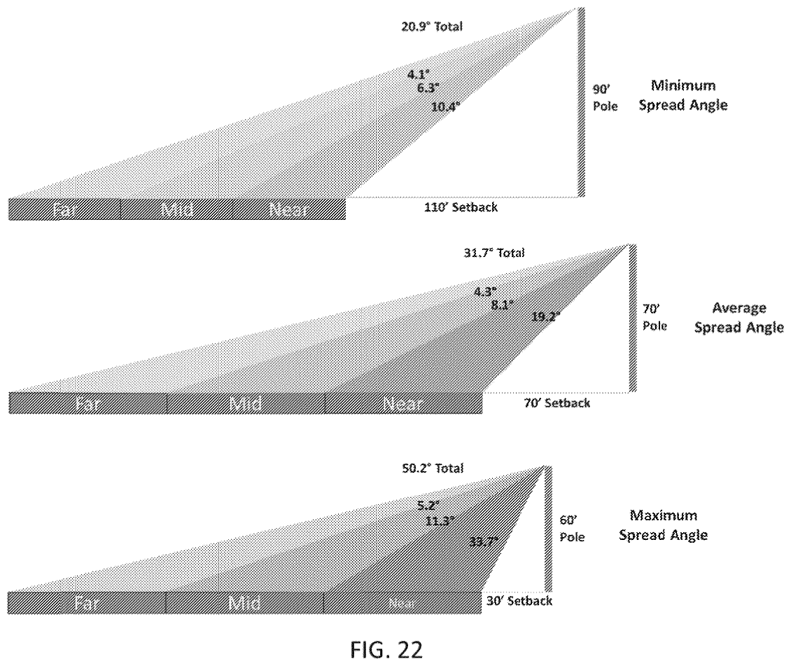

FIG. 23 is a schematic of tunable cut-off in a lighting system in accordance with an aspect of the present invention;

FIG. 24 is a perspective view of an environmental sealing system for a lighting module in accordance with an aspect of the present invention;

FIG. 25 is a front view of an environmental sealing system for a lighting module in accordance with an aspect of the present invention;

FIG. 26 is a side view of a micro-lens for a lighting module in accordance with an aspect of the present invention;

FIG. 27 is a first view of illumination steering using a lens array in accordance with an aspect of the present invention;

FIG. 28 is a second view of illumination steering using a lens array in accordance with an aspect of the present invention;

FIG. 29 is a third view of illumination steering using a lens array in accordance with an aspect of the present invention; and

FIG. 30 is a fourth view of illumination steering using a lens array in accordance with an aspect of the present invention;

FIG. 31 is a point-by-point overlay of the field shown with the pole locations indicated, as well as a fixture schedule and calculation results summary for each layout, in accordance with an aspect of the present invention;

FIG. 32 is a block diagram of a light a light fixture implementation system in accordance with an aspect of the present invention; and

FIG. 33 is a process flow diagram of the light fixture implementation system in accordance with an aspect of the present invention.

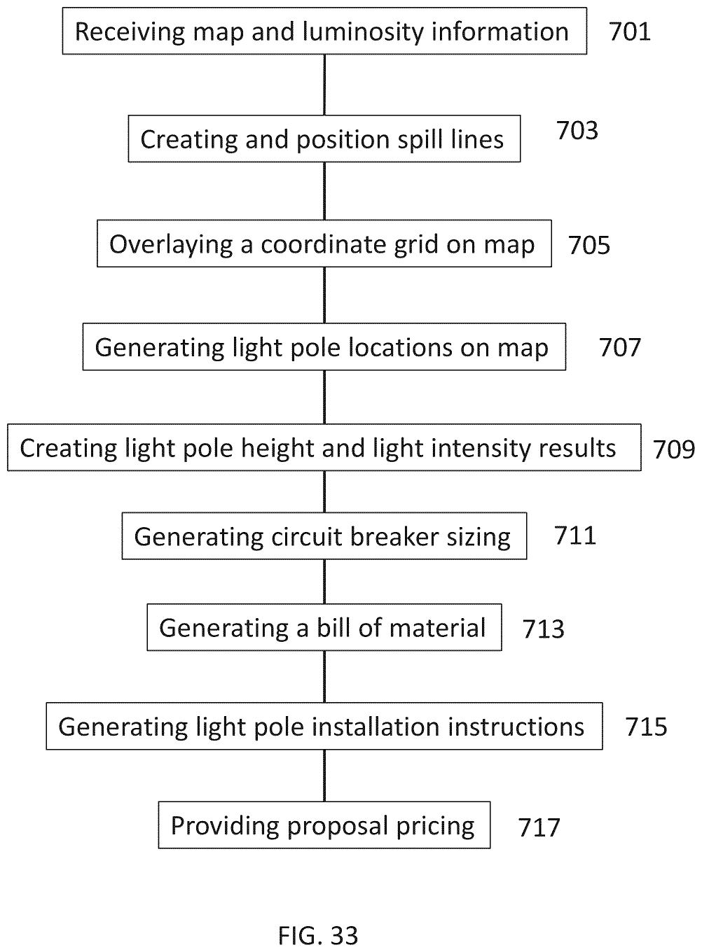

### DETAILED DESCRIPTION OF THE INVENTION

The present invention will be discussed in detail in terms of various exemplary embodiments according to the present invention with reference to the accompanying drawings. In the following detailed description, numerous specific details are set forth to provide a thorough understanding of the present invention. To those skilled in the art, it will be obvious that the present invention may be practiced without these specific details. Similarly, well-known structures are not described to avoid obscuring the present invention.

Thus, the implementations described below are exemplary implementations provided to enable persons skilled in the art to make or use the embodiments of the disclosure and are not intended to limit the scope of the disclosure, which is defined by the claims.

Furthermore, there is no intention to be bound by any expressed or implied theory presented in the preceding technical field, background, summary, or the following detailed description. It is also to be understood that the specific devices and processes illustrated in the attached drawings, and described in the following specification, are simply exemplary embodiments of the inventive concepts defined in the claims. Specific dimensions and other physical characteristics relating to the embodiments disclosed are not to be considered as limiting, unless the claims expressly state so.

Likewise, the various figures, steps, procedures, and workflows are presented only as an example and in no way limit the systems, methods, or apparatuses described to perform their respective tasks or outcomes in different timeframes or orders. Unless expressly stated, any method set forth herein shall not be construed as requiring that its steps be performed in a specific order. The teachings of the present invention may be applied to any asymmetric lighting system that has or is integrated with an auxiliary lighting system.

The various embodiments described herein provide for systems, devices, and methods for asymmetric lighting systems that have or are integrated with auxiliary lighting systems: particularly, for lighting systems for sports and auxiliary lighting systems for asymmetric source sports lighting systems.

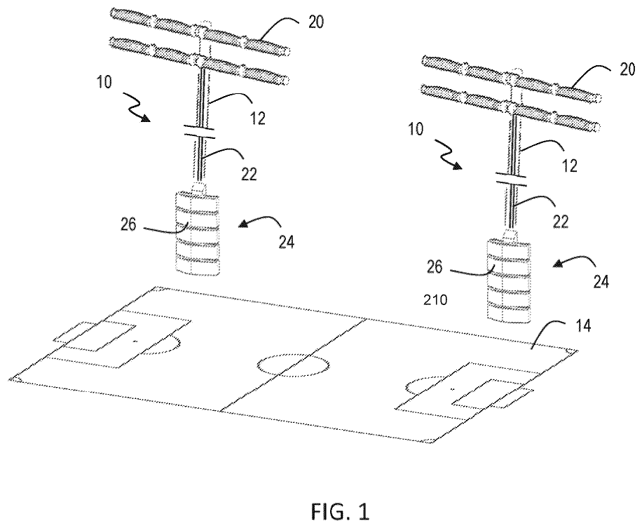

Referring to the figures, wherein like numerals refer to like parts throughout, there is seen in FIG. 1 an asymmetric source sports lighting system 10 according to the present invention. System 10 is designed for installation on a support pole 12 to provide illumination over a target area 14, such as a sporting field or pitch. The system 10 may also be used for lighting in outdoor parking areas, municipal street lighting, roadway lighting, or at any place where similar outdoor lighting systems are used. System 10 includes one or more rows of light emitting diode (LED) lighting modules 20 that extend laterally from support pole 12. Lighting modules 20 are powered via a wiring harness 22 that extends along the interior of support pole 12 and is coupled to a controller stack 24. Controller stack 24 transforms local building power from AC to DC and includes LED drivers 26 for lighting modules 20. A battery 210 is connected to support pole 12. The battery 210 may be directly connected to the controller stack 24, or the battery may be a separate unit connected by internal wiring to the controller stack 24. The controller stack 24 charges the battery 210 from transformed local building power while AC power is received by a power supply. In the event of black-out or brown-out conditions or a drop below a threshold voltage, the power supply is switched to battery power the lighting modules 20 or a subset of lighting modules. While a battery is described, a local electrical power storage of other kinds may be used in place of a battery.

In certain other embodiments, lighting modules 20 may include one or more columns of laser diodes (LD) instead of light emitting diodes. Controller stack 24 may also include LD drivers for lighting modules 20. The lighting systems described herein are LED based systems. However, the invention described could be used with LD based systems as well.

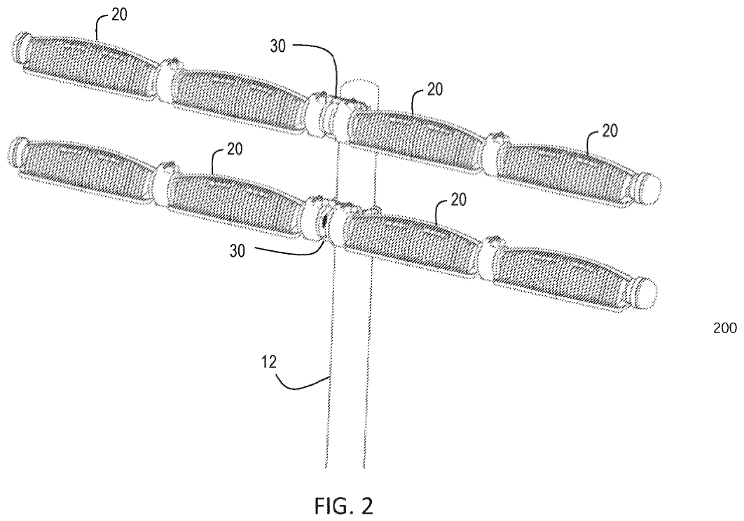

Referring to FIG. 2, a central mount 30 is coupled to pole 12 and used to support first and second lighting modules 20. Lighting modules 20 are coupled to either side of mount 30 using a modular coupling system described herein that physically supports modules 20 and electronically interconnects modules 20 to wiring harness 22 and thus controller stack 24. The opposing end of each lighting module 20 coupled to mount 30 may be used to physically support and electronically interconnect to additional lighting modules 20 extending further outwardly from support pole 12. The combination of lighting modules 20 connected to mount 30 and the additional lighting modules 20 extending to either side of pole 12 are self-supporting so that support pole 12 does not need to include physical cross-arms or lateral supports to mount additional lighting modules 20. The particular dimensions of lighting module 20 may be varied as desired. For example, lighting module 20 could be provided in two lengths, X and 2X, that may be mixed and matches as needed for a particular installation.

Continuing with reference to FIG. 2, two sets of lighting modules are depicted. The second set of lighting modules may be, for example, auxiliary emergency lighting 200. Auxiliary emergency lighting 200 may be turned off during normal lighting conditions and activated when emergency conditions arise. In other embodiments, auxiliary emergency lighting 200 may operate during normal lighting conditions but remain activated during emergency conditions.

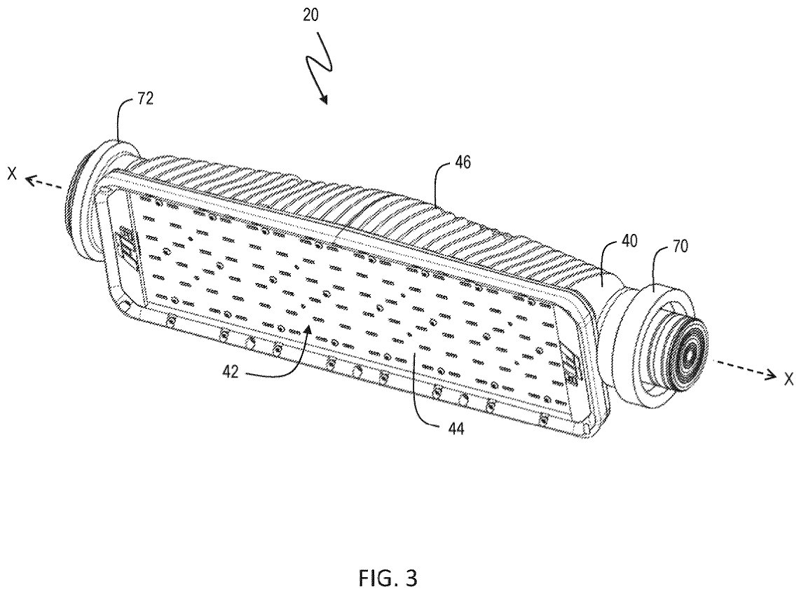

Referring to FIG. 3, each lighting module 20 includes a housing 40 extending along a longitudinal axis X-X. Housing 40 defines a rectangular opening 42 in a central portion thereof that permits access to an asymmetric illumination source 44. Asymmetric illumination source 44 is dimensioned to produce a rectangular beam of illumination from rectangular opening 42 of module 20. Housing 40 may further include fins 46 or other external structures for dispersing heat generated by using asymmetric illumination source 44.

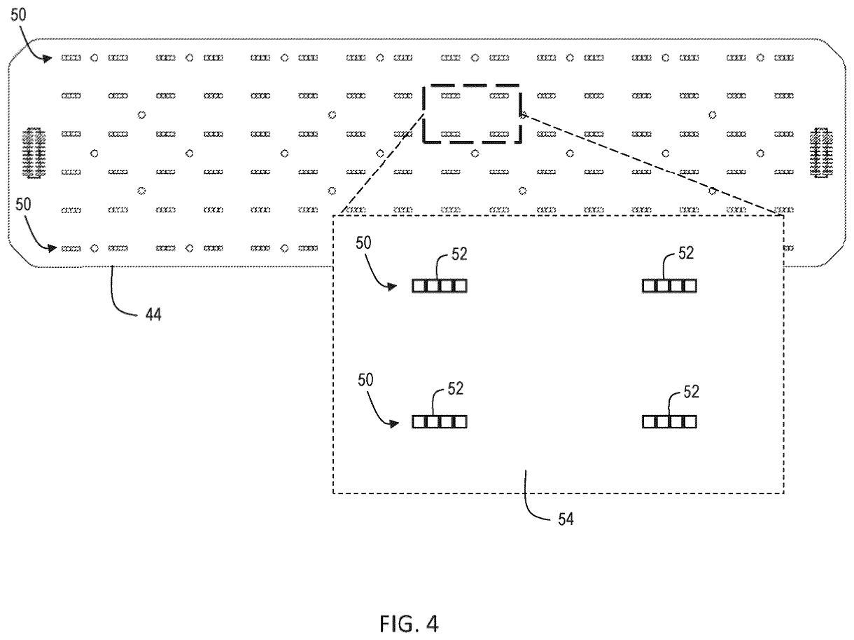

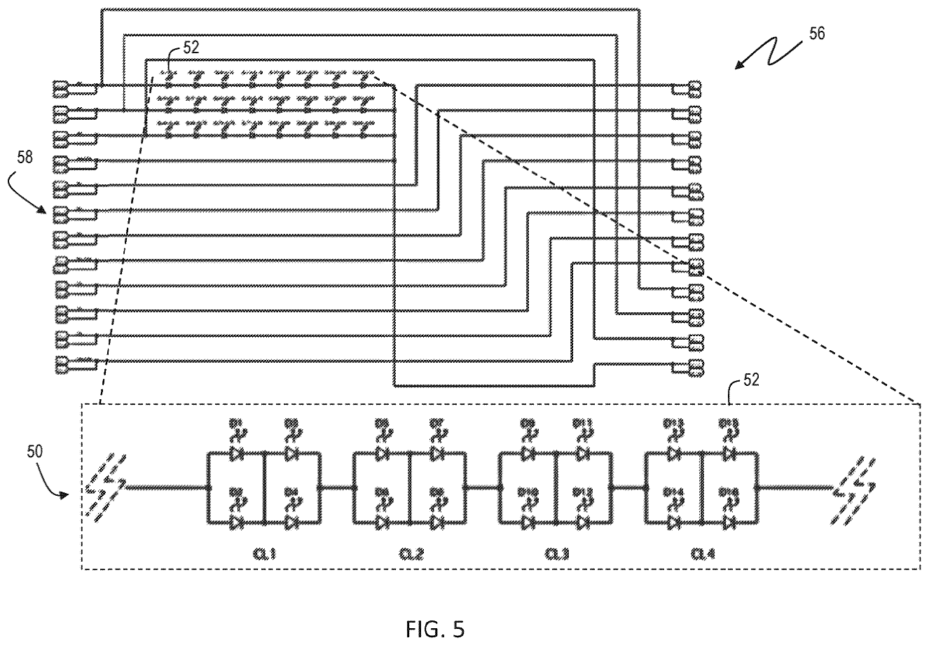

Referring to FIGS. 4 and 5, asymmetric illumination source 44 comprises multiple rows 50 of light emitting diode (LED) sets 52 spaced along a substrate 54 and coupled to electronic circuitry 56 for asymmetrically driving illumination source 44. Each row 50, or optionally, each pair of rows 50, are independently controllable by adjusting the amount of power delivered to that row (or pair or rows) using electronic circuitry 56 and controller stack 24 to provide asymmetric illumination from module 20. Optionally, a local microcontroller in each module 20 can be for further adjustment of the amount of power provided to each row (or pair or rows) of LED sets. As seen in FIG. 5, asymmetric illumination source 44 having three independently controllable rows 50 of LED sets 52. Electronic circuitry 56 further includes pass-through circuitry 58 for providing power to adjacently connected lighting modules 20 that also include independently controlled rows 50 of LED sets 52. In the example of FIG. 5, a total of two additional lighting modules 20 may be interconnected and supported by circuitry 58.

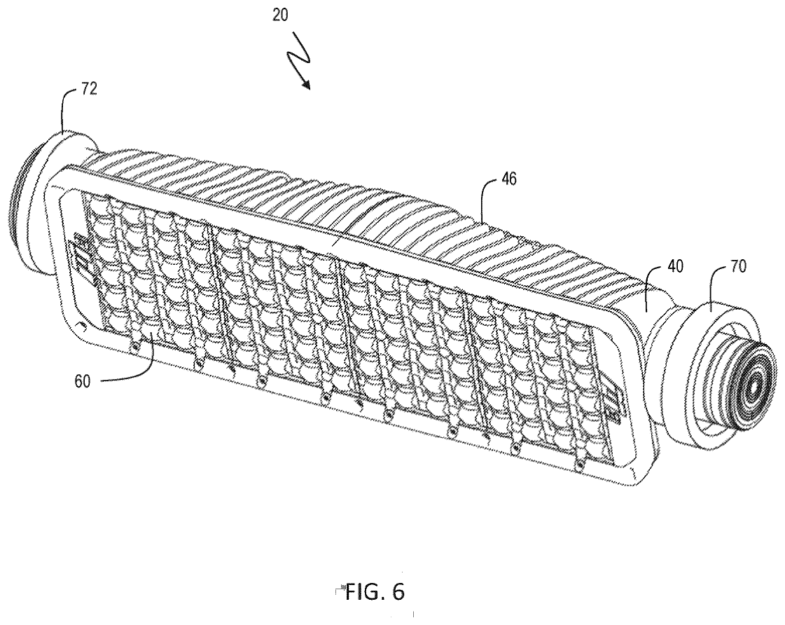

Referring to FIG. 6, a molded lens array 60 is positioned over an asymmetric illumination source 44 to reduce harshness and provide sealing of asymmetric illumination source 44 within housing 40. Housing 40 of module 20 is further configured to allow for easy coupling to the support pole and to other housings 40, forming both structural and electrical connection. Housing 40 includes a male coupler 70 positioned at one end of housing 40 and a female coupler 72 positioned at an opposing end of housing 40. Male coupler 70 is defined by a radially extending flange 74 and a circumferentially extending, outwardly facing bearing surface 76. Female coupler 72 includes a correspondingly dimensioned flange 78 and a receptacle 82 defining a circumferentially extending, inwardly facing bearing surface 77.

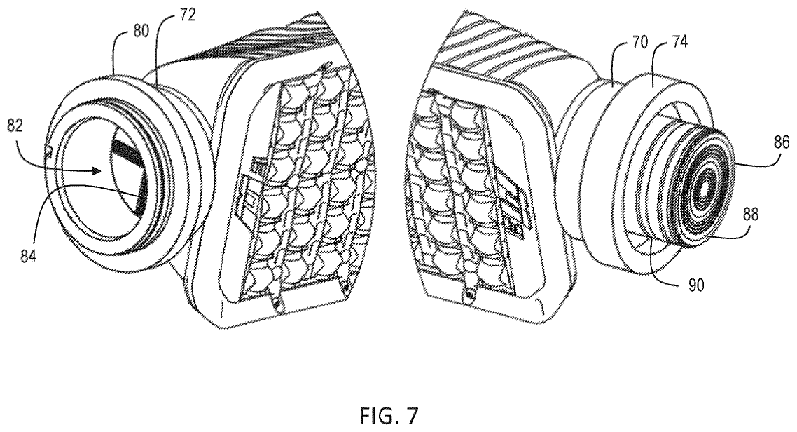

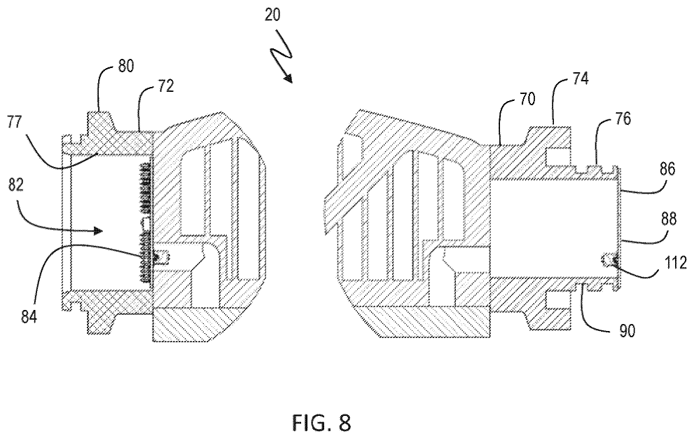

Referring to FIGS. 7 and 8, female coupler 72 further includes a set of brush contacts 84 positioned in receptacle 82 that face outwardly along axis X-X and male coupler 70 includes an end face 86 supporting set of ring contacts 88 that face outwardly in the opposite direction along axis X-X from brush contacts 84. Male coupler 70 may additionally include grooves 90 formed therein to house an O-ring for sealing purposes. It should be recognized that other contacts may be used, such as pogo pins and the like. As detailed below, brush contacts 84 and ring contacts 88 define a plurality of independent pathways for powering the independently controlled rows 50 of LED sets 52.

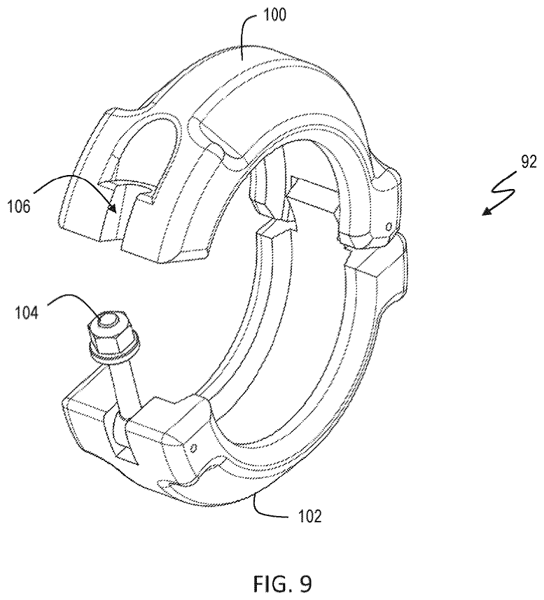

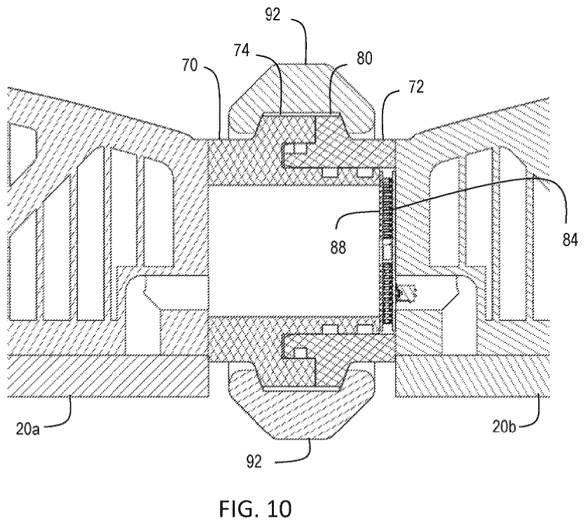

Referring to FIGS. 9 and 10, a clamp 92 may be positioned and secured in covering relation to flanges 74 and 80 to secure a first module 20 a to a second module 20 b when male coupler 70 and female coupler 72 are full joined so that bearing surfaces 76 and 77 are in seated together and brush contacts 84 and ring contacts 88 are in contact and electrically engaged. Clamp 92 comprises a pair of jaws 100 and 102 that can be opened and then closed in covering relation to flanges 74 and 80, as seen in FIG. 10, when male coupler 70 of one module 20 a is jointed with and seated inside female coupler 72 of an adjacent module 20 b. When male coupler 70 is fully inserted into female coupler 72, flanges 74 and 80 will abut and brush contacts 84 will physically and electrically engage ring contacts 88. Clamp 92 may then be closed over flanges 74 and 80 to secure first module 20 a to second module 20 b using a latch 104 on one jaw 102 that cooperates with a slot 106 in the other jaw 100, with electrical continuity between first module 20 a to second module 20 b provided via the engagement of ring contacts 88 with brush contacts 84. Adjacent modules 20 may thus be electrically interconnected when coupled together so that each module 20 has multiple independent electrical power pathways for driving the independently controllable LED rows of asymmetric illumination source 44.

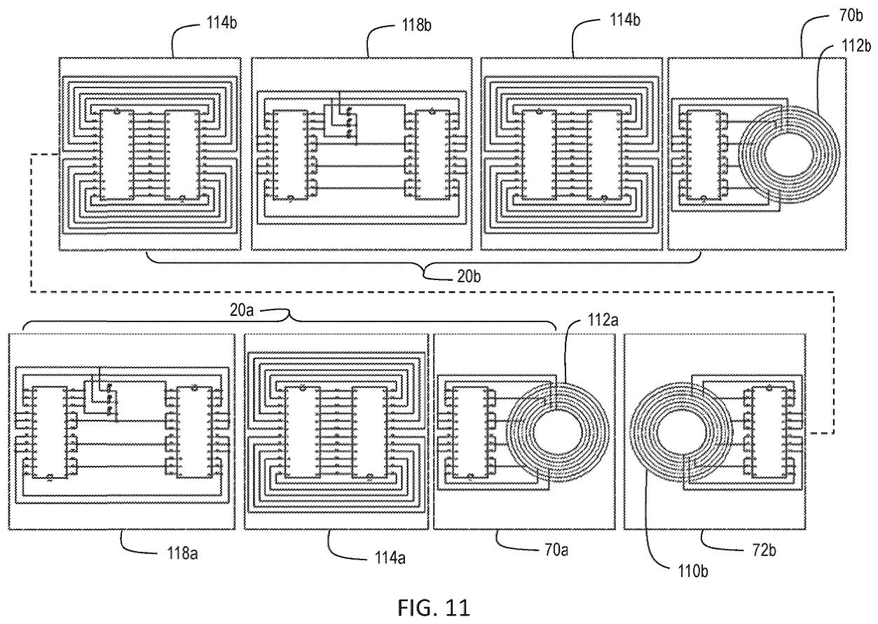

Referring to FIG. 11, module 20 b is electrically interconnected to module 20 a so that LED circuitry 118 b of module 20 b and LED circuitry 118 a of module 20 a are coupled together and under common power control. For example, coupler 70 b of module 20 b includes coupler circuitry 112 b that can receive power from ring contacts 88. Coupler circuitry 112 b is coupled to LED circuitry 118 b via cabling 114 b. LED circuitry 118 b is also coupled to coupler circuitry 110 b associated with female coupler 72 b via cabling 114 b. As a result, independent power pathways for LED circuitry 118 b extend through module 20 b and are available at coupler 70 b and coupler 72 b such as that a power supply connected to coupler 70 will also provide power to coupler 72, and vice versa. As further seen in FIG. 11, module 20 a can be electrically coupled to module 20 b via a coupler 70 a that is secured to coupler 72 b. Coupler circuitry 112 a of module 20 a is coupled to LED circuitry 114 a via cabling 114 a. Although not illustrated for simplicity, it should be evident that module 20 also includes a coupler 72 a that can be, in turn, coupled to another module 20, and so on, with the power supply for all housings 20 connected to an available coupler 70 or 72 at either end. Thus, module 20 is bi-directional and can be placed in series with additional housings 20 for common power control.

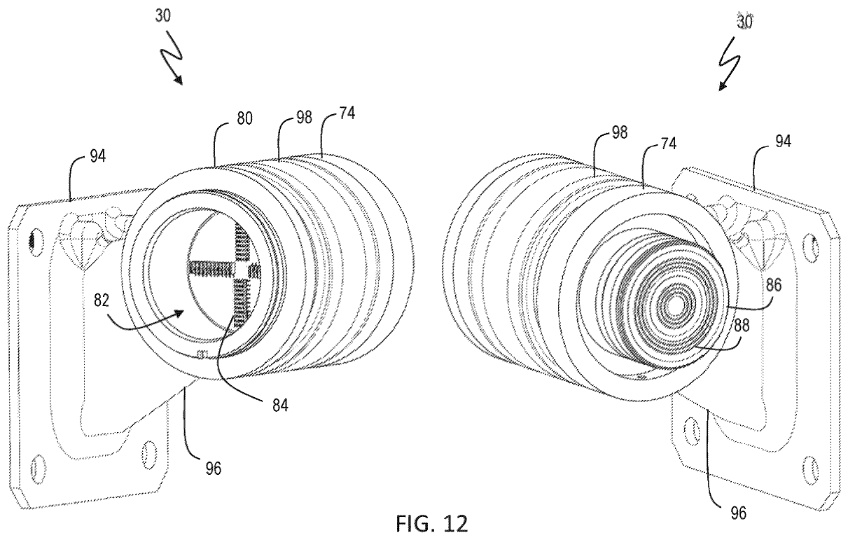

Referring to FIG. 12, mount 30 for attaching one or more housings 20 to a support pole 12 comprises a mounting plate 94 having a shaft 96 extending therefrom to support a main body 98 having male coupler 70 on one side and a female coupler 72 on the opposing side. Mount 30 suspends module 20 in spaced relation to support pole 12 to which mount 30 is attached. Male coupler 70 and female coupler 72 are configured in same manner as described above with respect to module 20, i.e., male coupler 70 includes an end face 86 having concentric ring contacts 88 and female coupler 72 has brush contacts 84 positioned within receptacle 82. Male coupler further includes flange 74 and female coupler 72 includes flange 80. As a result, module 20 may be coupled to mount 30 in the same manner as described above with respect to the connection of module 20 a to module 20 b.

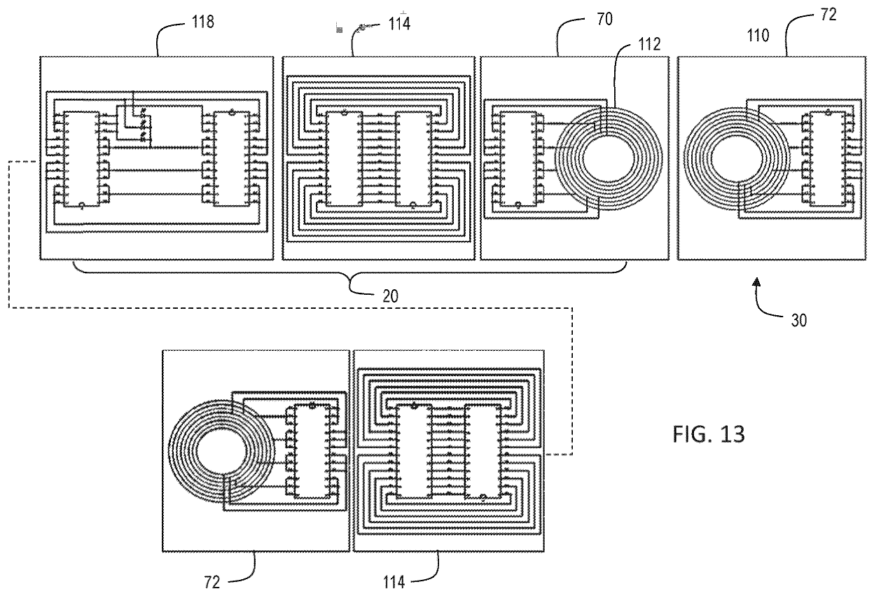

Referring to FIG. 13, joining of mount 30 to module 20 allows coupler circuitry 110 of female coupler 72 of mount 30 to connect with coupler circuitry 112 of male coupler 70 of module 20 via brush contacts 84 and ring contacts 88. Coupler circuitry 112 is coupled to LED circuitry 118 via cabling 114. LED circuitry 118 is also coupled to coupler circuitry 110 associated with female coupler 72 via cabling 114. As a result, independent power pathways for LED circuitry 118 b extend through module 20 from mount 30 and are available at coupler 70 such that a power supply connected to coupler 72 will also provide power to coupler 70. Similarly, module 20 may also be connected to the male coupler 70 of mount 30 using female coupler 72 of module 20, thus simply reversing the connections of FIG. 13 such that power is provided by mount 30 to coupler 72 with the power also made available at coupler 70 for attachment of another module 20.

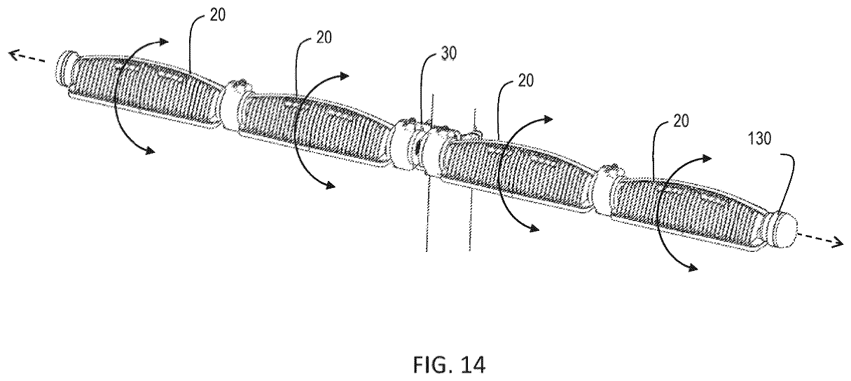

Referring to FIG. 14, cylindrical bearing surfaces of male coupler 70 and female coupler 72 allows adjacent lighting modules 20, as well as lighting modules 20 coupled to mount 30, to be rotated about longitudinal axis X-X. The orientation of the rectangular illumination provided by module 20 may thus be adjusted in a single direction, i.e., about a single axis, via rotation of lighting module 20 about axis X-X. As explained above, bearing surfaces 76 and 77 allow for physical rotation of housings 20, with brush contacts 84 and ring contacts 88 maintaining electrical continuity regardless of the rotation of housing about longitudinal axis X-X. Housings 20 may thus be easily oriented, or reoriented, as desired. While housings 20 may be manually adjusted at any time, servo motors could be incorporated into couplers 70 and 72 to allow for remote rotation of lighting modules 20 about axis X-X.

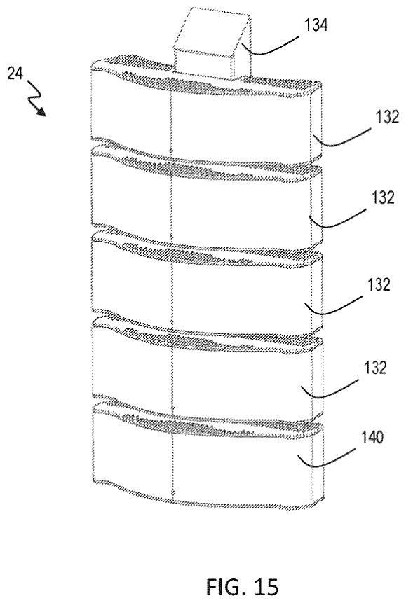

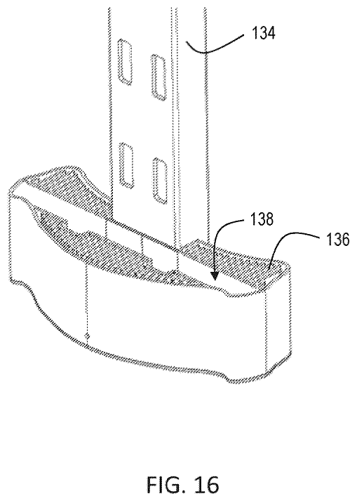

Referring to FIGS. 15 and 16, controller stack 24 comprises a series of core enclosures 132, each of which houses the power conversion and LED electronics, typically referred to as LED drivers, for an associated lighting module 20, as well as a master enclosure 140 that provides housekeeping functions. Controller stack 24 includes a back plane 134 that provides the electrical interconnections between each core enclosure 132 and master enclosure 140 as well as the requisite interconnections to wiring harness 22 to interconnect controller stack 24 to lighting modules 20. Back plane 134 is preferably adapted to act as a heat sink and transfer excess heat to support pole 12 for additional dispersion of heat generated by controller stack 24. As seen in FIG. 16, core enclosure 132 and/or master enclosure 140 include ribs 136 for dissipation of heat generated by internal electrical components positioned in a central cavity 138.

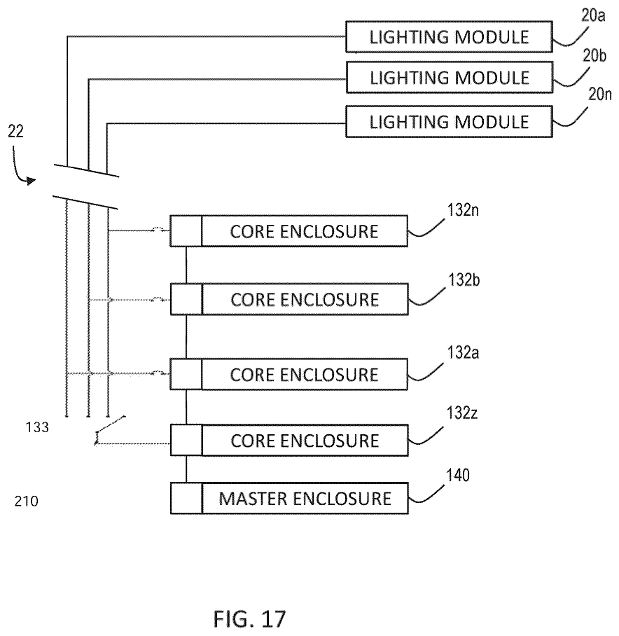

Referring to FIG. 17, each core enclosure 132 a, 132 b . . . 132 n is associated with and coupled via wiring harness 22 to a corresponding lighting module 20 a, 20 b . . . 20 n. Preferable, a backup core enclosure 132 z is selectively coupled to each lighting module 20 a, 20 b . . . 20 n via a switching circuit 133 to provide a backup power supply in the event of a fault in any of core enclosure 132 a, 132 b . . . 132 n. For example, if a fault in any core enclosure 132 results in the loss of illumination from any or all of the independently controlled rows 50 of LED sets 52 in the corresponding lighting module 20, power to that lighting module 20 can be switched to the backup core enclosure 132 z to maintain the desired amount of illumination until such time as the faulty core enclosure 132 can be repaired or replaced. Each core enclosure 132 a, 132 b . . . 132 n is also interconnected to master enclosure 140, which supervises and controls via digital commands the local operation of each core enclosure 132 a, 132 b . . . 132 n.

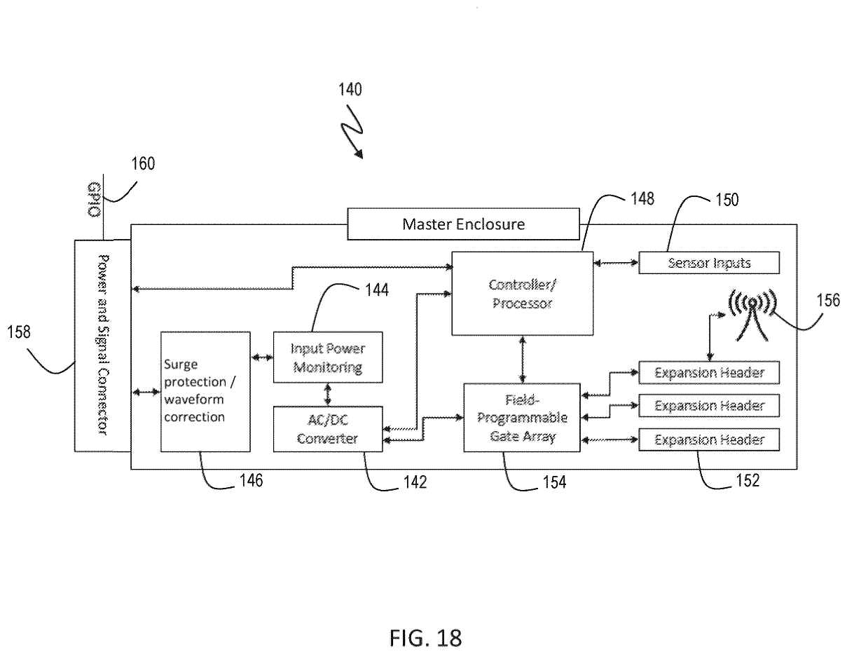

Referring to FIG. 18, master enclosure 140 is coupled to AC power via a power and signal connector 158 and includes local AC/DC conversion 142 with input power monitoring 144 as well as surge protection and waveform correction 146. Master enclosure 140 also includes a controller/processor 148 that has sensor inputs 150 for monitoring of system 10. Controller/processor 148 is also interconnected to a series of expansion headers 152 and wireless communication interface 156 via a field programmable gate array (FPGA) 154.

Controller/processor 148 may thus be programmed to establish connection with a remotely positioned host system or remote device (such as a tablet or smartphone) that can provide commands controlling operation of lighting modules 20 using expansion headers 152 to provide the desired wireless connectivity. Communication could comprise any conventional wireless communication technology or protocol, such as WiFi, Blutetooth®, BLE, ZigBee, Z-Wave, 6loWPAN, NFC, cellular such as 4G, 5G or LTE, RFID, LORA, LoRaWAN, Sigfox, NB-IoT, or LIDAR. Controller/processor 148 is also coupled via power and signal connector 158 for communication with core enclosures 132, such as via a general-purpose input/output (GPIO) line 160, extending in back plane 134.

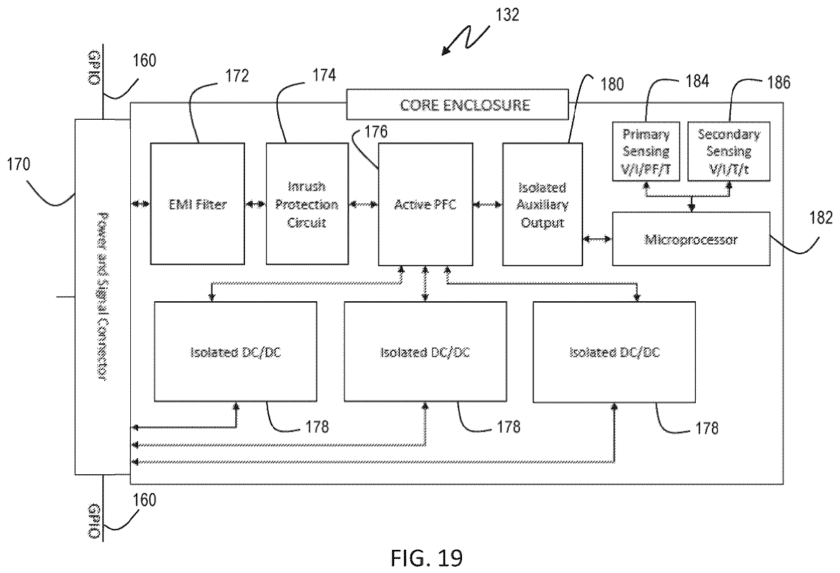

Referring to FIG. 19, each core enclosure 132 includes a power and signal connector 170, which provides connectivity to master enclosure 140 via GPIO line 160 as well as to a connection to AC power. Core enclosure 132 provides power conversion to DC and power conditioning via an EMI filter 172, an inrush protection circuit 174 and an active power factor corrector (PFC) 176. A plurality of isolated DC/DC circuits 178, each of which supports a corresponding one of independently controllable LED rows of asymmetric illumination source 44, are coupled to active PFC 176. The present invention is illustrated with three isolated DC/DC circuits because the exemplary illumination source 44 has three independently powered rows of LEDs, but if asymmetric illumination source 44 included four independently controlled rows 50 of LED sets 52, four isolated DC/DC circuits 178 would be included. Core enclosure 132 further comprises an isolated auxiliary output 180 coupled to a microprocessor 182. Microprocessor 182 is further coupled to primary sensing circuits 184 and secondary sensing circuits 186 for monitoring voltage, current, power factor, and temperature across system 10. Microprocessor 182 is further configured to adjust the power output from each of the plurality of isolated DC/DC circuits 178 based on monitoring of primary sensing circuits 184 and secondary sensing circuits 186. For example, if one of independently controlled rows 50 of LED sets 52 is not operational, microprocessor 182 can adjust the power output from the isolated DC/DC circuits 178 for the other of the independently controlled rows 50 of LED sets 52 to compensate for the loss and ensure that asymmetric illumination source 44 is providing the desired amount of illumination.

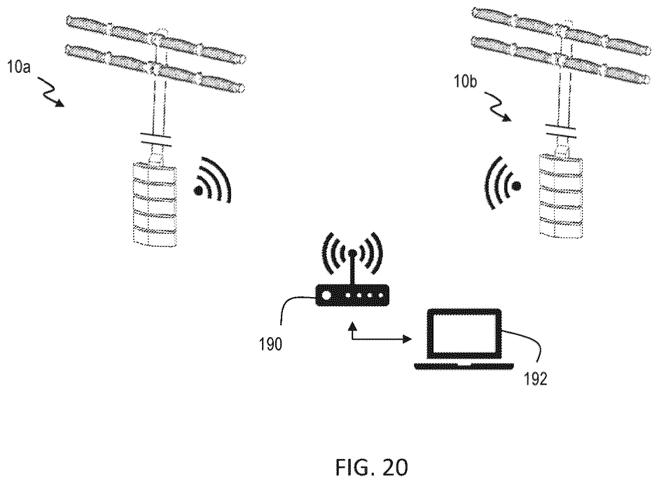

Referring to FIG. 20, the wireless communication capability of master enclosure 140 provides a third layer of redundancy in the event of a partial or total loss of illumination from lighting module 20. For example, a detected loss at one location of system 10 may be communicated to wireless gateway 190 and remote host 192. The illumination output of another system 10 b may then be adjusted accordingly, either by allowing a user to send a command to system 10 b to adjust power to lighting modules 20 to compensate for the detected loss or by supervisory software residing on host 192 that automatically sends the appropriate commands.

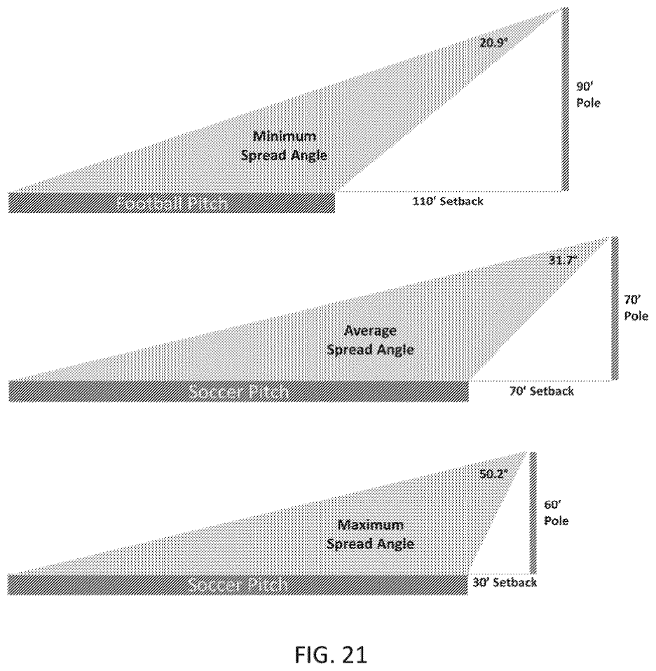

Referring to FIG. 21, asymmetric illumination source 44 of each module 20 allows for remote beam steering of lighting system 10. Lighting system 10 may be adapted to a particular installation regarding of the width of the pitch to be illuminated, the height of support pole 12, and the distance between support pole 12 and the targeted pitch. For example, asymmetric illumination source 44 may be driven to change the beam angle (generally recognized as the region of illumination with at least fifty percent of the maximum beam strength) to provide the appropriate amount of illumination between a minimum and maximum spread angle encountered in an installation. In the first scenario of FIG. 19, where the height of support pole 12 and setback distance require a minimum spread angle, asymmetric illumination source 44 can be driven asymmetrically in a first configuration to provide a narrow beam angle without having to physically reorient modules 20. In the last scenario, where the height of pole 12 and setback distance require a minimum spread angle, asymmetric illumination source 44 can be driven asymmetrically in a different configuration to provide a broader spread angle without having to physically reorient modules 20. Thus, the effective positioning of modules 20 can be adjusted without actually having to physically reorient modules 20. Thus, modules 20 may be asymmetrically driven to change the illumination scenario for different events or conditions, or to simply adjust the illumination in a given location without having to physically move lighting modules 20. FIG. 20 illustrates how the power control over each row 50 of asymmetric illumination source 44 can be adjusted to impact the beam angle emitted from lighting module 20 without having to rotate lighting module 20.

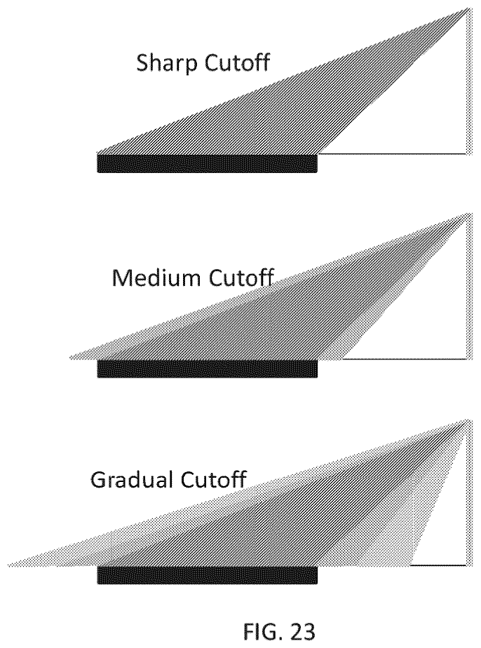

Referring to FIG. 23, asymmetric illumination source 44 of each lighting module 20 provides for a tunable cut-off for the illumination generated from lighting module 20. Illumination cut-off generally refers to the amount of illumination in the beam field that extends beyond the desired beam angle (any area of illumination with less than fifty percent but more than ten percent of the maximum beam strength). For example, in the first scenario of FIG. 23, the cut-off is very sharp, i.e., there is very little spillage beyond the main beam angle. In the second and third scenarios, the spillage increases such that more illumination is provided ancillary to the primary beam angle. Asymmetric illumination source 44 may be driven to change the cut-off at any time, whether finally upon installation, or dynamically over time to change the lighting scheme as desired by a user for different applications. For example, a gradual cut-off may be selected when more light is desired in the areas surrounding a pitch for a particular event, such as a pre-game show, and then adjusted to provide a sharp cut-off during a game. Thus, asymmetric illumination source 44 allows for control over both the beam angle and the beam field relative to each other and relative to the illumination target.

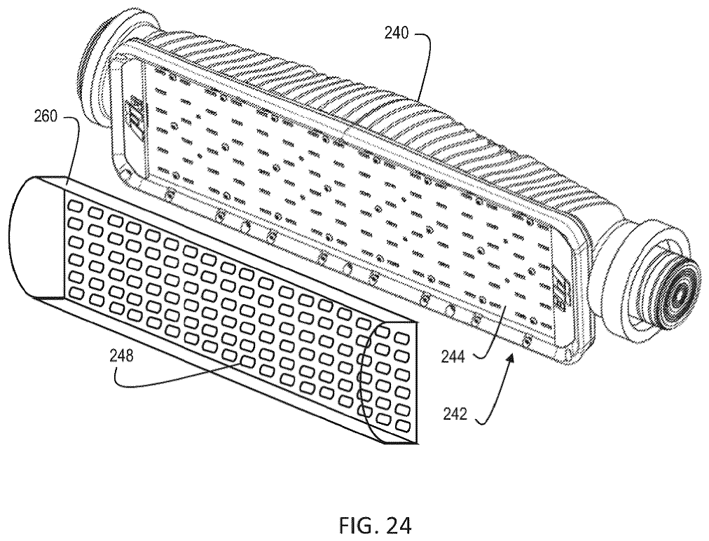

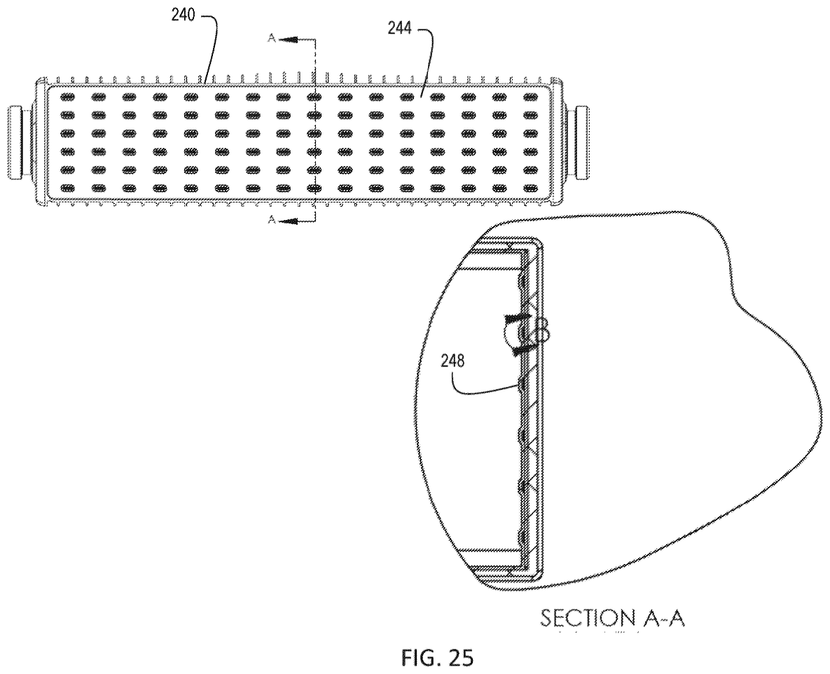

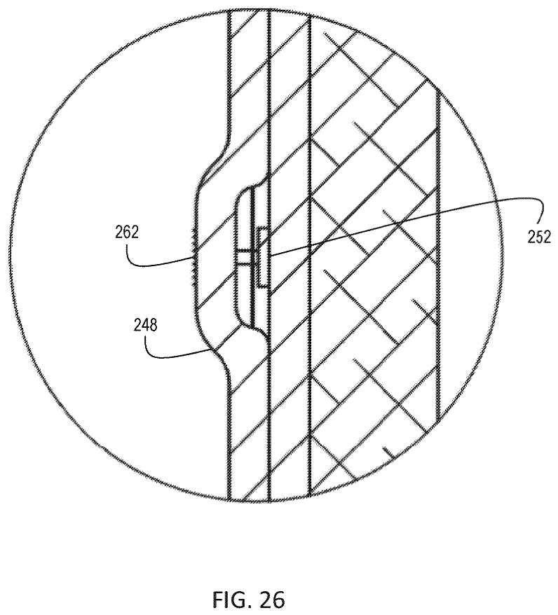

Referring to FIG. 24, lighting module 20 may be constructed using a housing 240 that encloses an asymmetric illumination source 244 and is environmentally sealed prior to attachment of lens array 260. As seen in FIG. 25, housing 240 includes a resilient optical layer 248 positioned over asymmetric illumination source 244 and captured within rectangular opening 242 to seal housing 240 from environmental infiltration. As a result, lens array 260 may be attached or removed from housing 240 in the field, such as to adjust the optical conditioning being provided, without compromising the environmental integrity of housing 240. Optical layer 248 is preferably formed from a moldable optical silicone, such as SILASTIC® MS-1002 moldable silicone and related moldable silicone compounds. As seen in FIG. 26, optical layer 248 may include micro-lenses 262 molded therein and in alignment with each LED set 252 of asymmetric illumination source 244. Optical layer 248 thus performs pre-modulation of the illumination from lighting module 20. Micro-lenses 262 allow for finer optical texturing than with lens array 260 alone. In addition, as lens array 260 does not need to perform as much optical conditioning, lens array 260 can be smaller and thus lighter than otherwise possible.

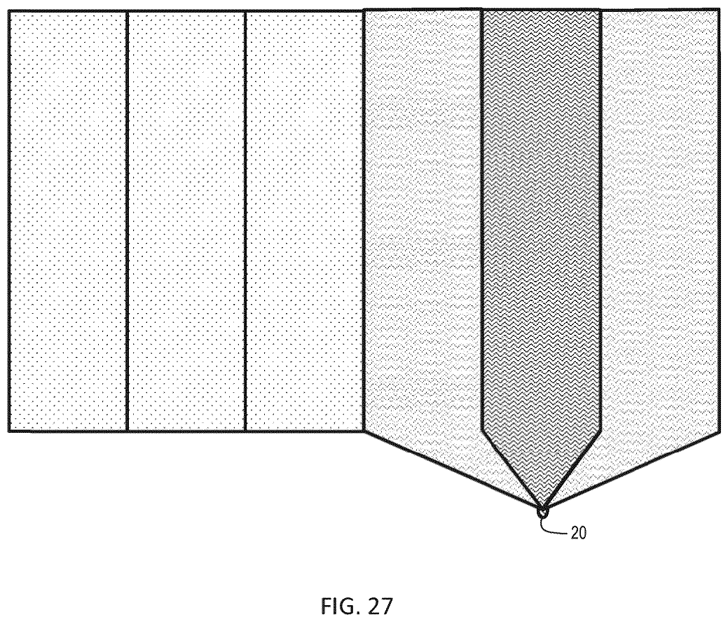

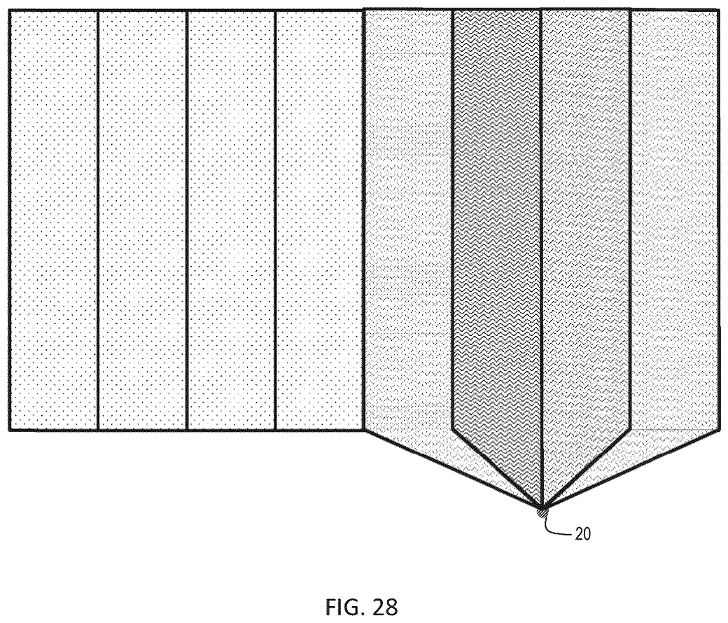

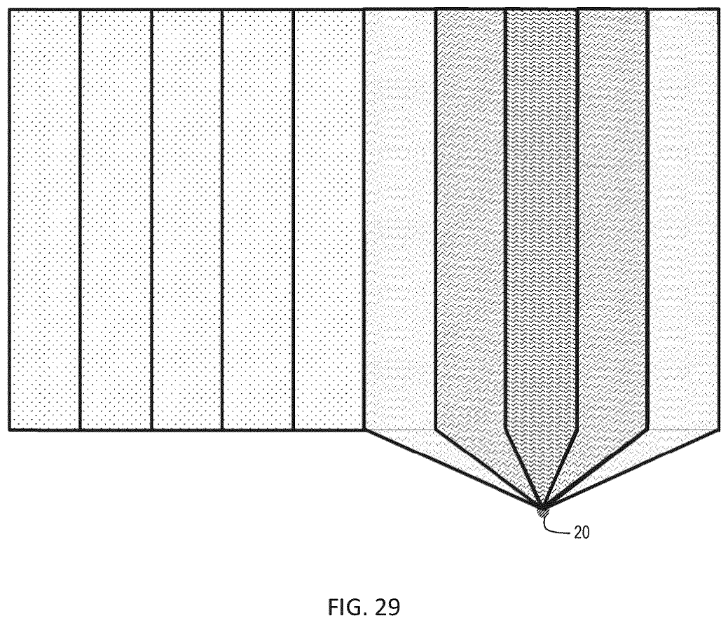

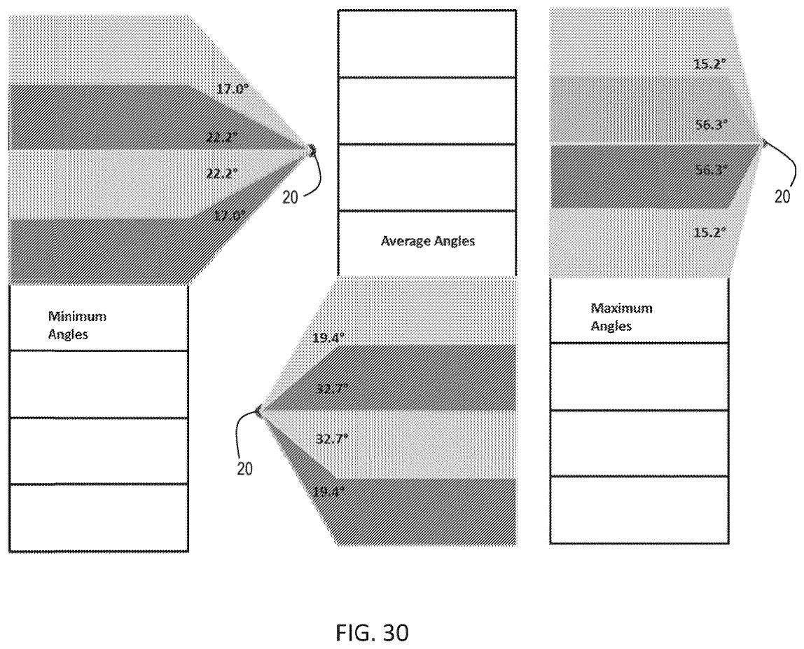

Referring to FIGS. 27 through 30, lighting module 20 may be outfitted with lens array 60 configured that steers illumination into three, four, or five different regions. For example, each particular installation may include a different number of support poles 12, so an appropriate lens array 60 distributing illumination into three, four, or five different regions may be used. As is known in the field, illumination from each support pole 12 may need to overlap with illumination for other support poles 12 to provide the desired illumination, reduce or control shadowing, etc. As seen in FIG. 30, lighting module 20 can provide a wide or narrow area of illumination using variously designed lens arrays 60 to steer illumination between a minimum and maximum distribution angle.

Various specialized companies may be called on to create submittal packages for projects that contain point-by-point calculations to optimize the fixture aiming. The process for typical fields may be streamlined by a photometric and proposal automation software tool that provides for users to drop poles onto a layout image of a field, specify the field type, and then the tool will select the best lighting fixture for each pole and determine the optimal aiming details of those fixtures. The sports lighting tool may also create and be configured for sharing of a set of project specifications and calculation results.

The sports lighting layout tool may include a web application or computer application or software (“Lighting Layout Application”). The Lighting Layout Application may run on a first computer device, such computer device having at least one processor, memory, and at least one storage device (e.g., non-transitory storage device). The first computer device may include a desktop computer, a laptop, a server, and/or a mobile computing device, such as a mobile phone or a tablet. In certain other embodiments the first computer device may be a plurality of computer devices in network communication with each other.

In certain other embodiments, the sports lighting tool may form a networked system (Sports Lighting Layout System) and may include a second computer device, such as a desktop computer, a laptop, a server, and/or a mobile computing device, such as a mobile phone or a tablet. In certain other embodiments, the second computer device may be a plurality of computer devices in network communication with each other. The Lighting Layout Application may be accessible on modern browsers on the second computer device or may be accessible by a software application running on the second computer device.

The Lighting Layout Application may include a database on the first computer device, the database configured for storing user and project information. The database may be connected to backend system for authentication and project access. The backend system may be on the same computer device as the database or another computer device, the two computer devices connected by networked communication. A frontend system of the Lighting Layout Application may include features for display the application, providing for access by a user for data input and receiving data output. The Lighting Layout Application may also include a calculation engine. The Lighting Layout Application may include all or parts of the frontend system, the calculation engine, and the backend system.

The frontend may be accessible through a browser (e.g., web application) or it may be accessible through a software application running on a second computer device or it may be the software application running on the second computer device.

The Lighting Layout Application may also include may also display satellite images of outdoor fields may have a built in email system, phone notifications, and an authentication system.

The database is configured to be updatable and may include user login information. In certain embodiments, passwordless authentication may be implemented, but in other embodiments passwords may still be used to maintain security. Other common security measures for software access may also be implemented. For example, users may register with an email address and a phone number, which may be verified via authentication codes. When the user attempts to log in from a new computer device, an authentication code and authentication link will be sent to the email, and an authentication code will be sent to the phone number on record.

Upon registering, a user may be set to a “pending approval” stage, and an email will be sent to a specified system administrator to approve that user. Users may also be approved in a web administrator interface.

Users may be required to provide their full name, email address, phone number, company name, and location. Administrators will be able to see the following information for each user: Name, email, phone, company name, location; List of projects/layouts; # of calculations. Administrators may be able to lock out users.

Users and administrators may be associated with a particular company and information may be shared within that particular company but not outside.

The Lighting Layout Application may include organization that identifies a project. The project may include identifying information such as a project name, location, and client information. Projects may be shared with other registered users, and may be shared with all users within the same Company (e.g., this may be verified by email domain matching). Projects may also be Published to anyone with a unique link for viewing only. Published projects may contain limited access and information such as only displaying the Published Layouts contained within them.

A project may have one or more fields associated with the project, which may be defined by a field type (e.g., football, baseball, softball, soccer, lacrosse, tennis, rugby, field hockey, cricket, track and field, etc.), a background image, size, and a calculation grid. The most common field types include football, soccer, baseball, and softball.

Each field may have one or more layouts, which may be defined by pole location, mounting height, fixture type, quantity, and aiming. Each layout may have corresponding output data. Layouts may be private (e.g., visible only to registered users) or published to non-registered users via a unique project link. The components of a field within the system may be understood as a field definition.

Initially, field definition may include just the field type and the calculation grid. Main field grids may also be included, at first. The entire process of field, layouts, calculations, and reports may be pursued for a single field type first (e.g., football) and then expanded to other common field types.

When the field definition is completed, users may be able to browse an ariel view map to locate a field and align the calculation grid to the satellite image. For baseball and softball fields or other field types that are non-symmetrical or have sections with different lighting needs, a plurality of grids may be used. For example, for baseball and softball fields there may be separate infield and outfield grids. Outfield grids may be defined by a polyline drawn on the ariel view to specify the perimeter. There may also be an optional trespass grid, which may be drawn as a polyline on the ariel view or set to a specified offset from the main grid.

Initially, layouts may use pole locations defined by distance from the field center. Each layout may have a lighting requirement for maximin uniformity and average light level (e.g., specified either by typical built in IES or other organization specifications, or user defined).

A completed layout may be configured to allow users to drop and place and verify the pole location on the satellite image.

An initial implementation calculation may include user input to specify the type of fixture for each pole, the quantity of fixtures for each pole, and the aiming angle of each pole. The system may then compute the light levels. This mode may always be available for users that want to do their own design or modify the design resulting from through a generated optimization layout.

Output may also be enhanced by selecting maximized uniformity and target efficiency (e.g., Equal fixture count per pole). For fields with nearly symmetric pole positions, the automated design routine may begin with one fixture per pole to determine the optimal aiming. The fixture type may be determined by the field type and pole position. For each pole, the Lighting Layout Application may run through the range of possible aiming angles, tracking the resulting field uniformity and target efficiency (e.g., the percent of light onto the field) for each option.

The Lighting Layout Application may then sort these results, removing any uniformities that are not within the requirements, and then selecting the solution with the highest target efficiency (e.g., this may mean the fewest required fixtures). For fields with two or more grids (e.g., baseball & softball) this task may be repeated separately for each grid and its respective poles. For example, the infield may be optimized first, followed by the outfield second.

Based on the required light levels, the number of fixtures per pole may then be determined based on the light levels from one fixture per pole. If there are no results with acceptable uniformities, the process may proceed to a third step.

If the pole placement is not symmetric or the uniformity could not be achieved with an equal number of fixtures per pole, the Lighting Layout Application may consider the quantity of fixtures per pole in the optimization. This is known as optimize fixture quantity per pole. Because this introduces another variable, it may increase the calculation time.

Result and output reports may be generated by the Lighting Layout Application. All reports may share a common format. There may be fields for Customer Name and a customer logo that may be swapped out on a per-user or per-company basis. Each project output may include a project summary and overview, including: a title page with summary information for all published layouts having a field type, a pole label, a fixture count per pole, total fixture count per type, and total wattage. Finally, the report may include an achieved average light level and uniformity for that field.

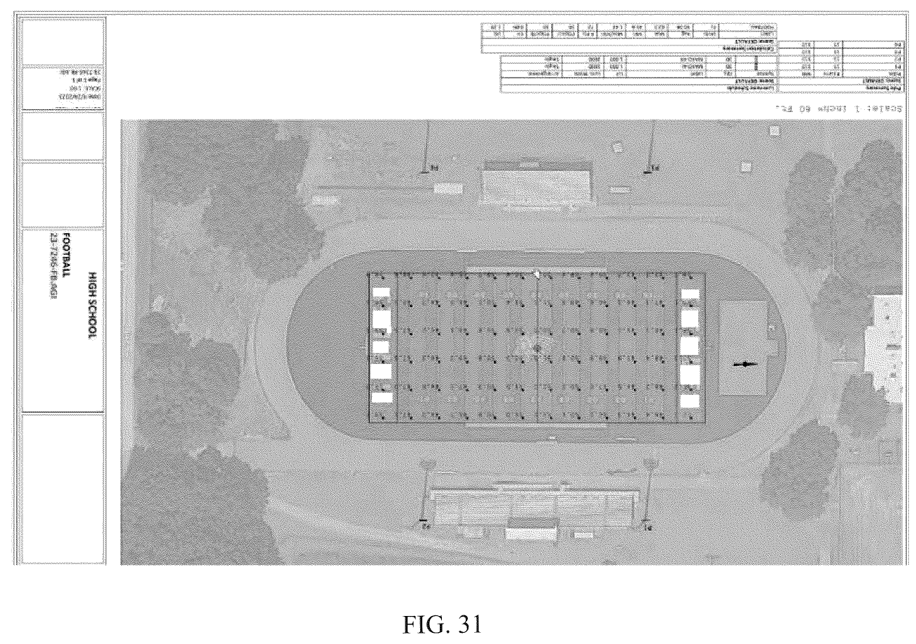

An overall point-by-point diagram may be generated. As shown in FIG. 31, a point-by-point overlay of the field is shown with the pole locations indicated, as well as a fixture schedule and calculation results summary for each layout.

A fixture aiming diagram may also be provided. For each pole, the fixture aiming diagram may be included, and the fixture aiming diagram the aiming point or points on the field.

Finally, the output may include a pole rack diagram showing for each pole, a diagram showing each fixture and its aiming.

As an example, a method for executing instructions in a lighting layout system includes a computer readable program providing instructions to a processor in a computer device, the computer device having storage, memory, and input device, and an output device the computer readable program providing instructions and the processor executing the instructions. The lighting layout method includes receiving an input layout having: a project identifier, including a project name, a location, and client information; field information, including at least one field image, a field type, a background image, a size, and a calculation grid; field luminosity information; a field layout associated with the field information, including a quantity of poles, pole locations, a fixture mounting height, a fixture type, a quantity of fixtures, and aiming information. The lighting layout method includes processing the input layout using the processor. The lighting layout method includes creating an output having: a field type; the quantity of poles and pole locations; a pole label; a fixture count per pole; a total fixture count per type; a total wattage; an achieved average light level and uniformity result; a point-by-point overlay of the field with the pole locations indicated, the fixture schedule, and the results summary for each layout; an aiming diagram showing the aiming point on the field for each pole; and a rack diagram showing each fixture and its aiming for each pole. The method includes displaying the output by the output device.

The input layout of the method for determining a lighting layout may further include a second calculation grid for non-symmetrical field types. The output of the method for determining a lighting layout may further include adjusted pole locations based on lighting requirements. The output of the method for determining a lighting layout may further include light levels. The output of the method for determining a lighting layout may further include an aiming angle. The output of the method for determining a lighting layout may further include a plurality of aiming angles and field uniformity and target efficiency data associated with each of the plurality of aiming angles. The output of the method for determining a lighting layout may further include adjusting the quantity of poles. The output of the method for determining a lighting layout may further include adjusted pole locations based on lighting requirements for the calculation grid and for the second calculation grid. The output of the method for determining a lighting layout may further include spill lines. The method for determining the lighting layout of claim 1, further including entering data by the input device to adjust the input layout. The method for determining a lighting layout of claim 1, further including entering data by the input device to adjust the output.

As an example a lighting layout system for executing instructions includes: receiving an input layout having a project identifier, field information, field luminosity information; a field layout associated with the field information; processing the input layout using the processor; creating an output having a field type, the quantity of poles and pole locations, a pole label, a fixture count per pole, a total fixture count per type, a total wattage, an achieved average light level and uniformity result, a point-by-point overlay of the field, an aiming diagram showing the aiming point on the field for each pole, and

a rack diagram showing each fixture and its aiming for each pole; and displaying the output by the output device. The project identifier includes a project name, a location, and client information. The field information includes at least one field image, a field type, a background image, a size, and a calculation grid. The field layout associated with the field information, includes a quantity of poles, pole locations, a fixture mounting height, a fixture type, a quantity of fixtures, and aiming information. The point-by-point overlay of the field includes the pole locations indicated, the fixture schedule, and a results summary for each layout.

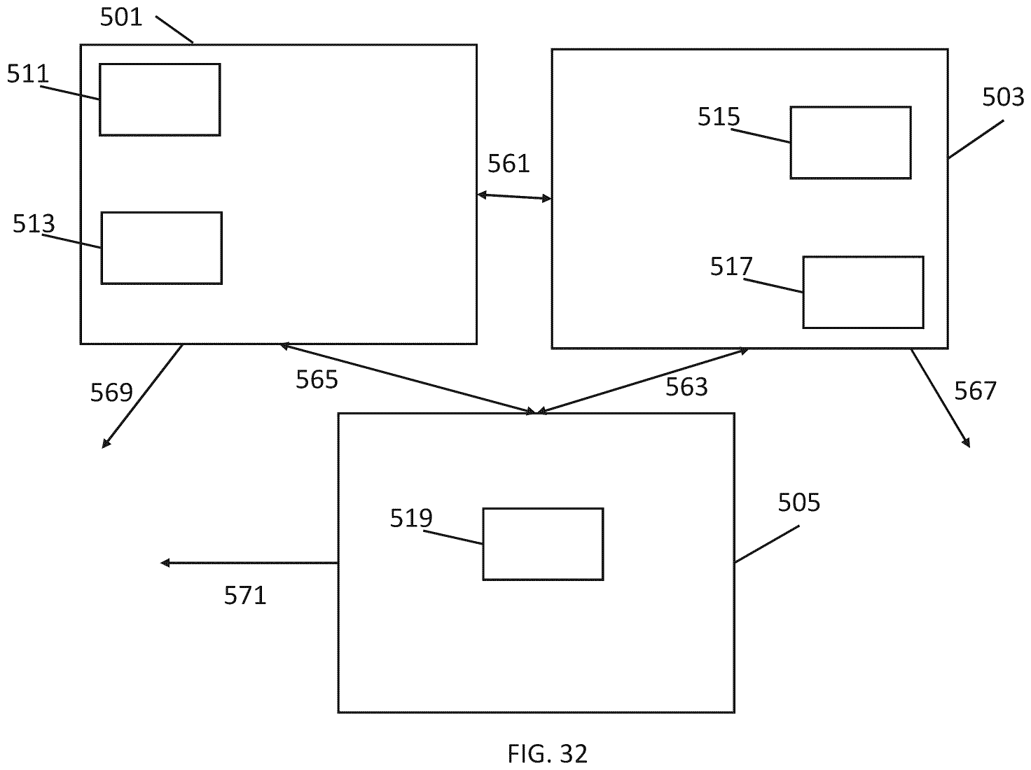

With reference to FIG. 32, the Lighting Layout Application may include three parts: a design module 501; a specification module 503, and a build module 505.

The design module may have or be in communication with a software application to provide for lighting system design layouts. A photometric automation module 511 may provide computer aided designs and drawings based on facility parameters provided by the user. For example, the photometric automation module 511 may have import and export data communication with a lighting design and simulation tool such as, for example, Agi32™.

The design module may include a spill light calculation module 513. Calculations may be made at a user specified offset distance (e.g., 150 ft is a commonly used offset). The offset may vary with the type of sports field. Spill lines may be calculated if a satellite map or other overhead viewed map of the facility is provided to the design module. In one embodiment, input may be provided by a download from mapping software, such as, for example, Google Earth™ or similar software. Mapping may include positioning coordinates to aid in positioning other objects relative to the map. Light sensors placed on positions on the field and coordinated with the satellite map to determine light conditions (e.g., luminosity) at various positions on the map. Such light sensors may be in communication contact with the design module, but users may also be able to manually input lighting information. Based on positioning and light inputs, spill lines may be generated. If spill line calculations cannot be made based on a map and lighting information, the lines may be manually added or adjusted. In certain embodiments, on-field luminosity calculations may be made based on the map and spill lines.

In certain embodiments, the design module may provide proposal pricing using parameters collected by the design module. In certain other embodiments, real-time feedback may be provided to the design module from the light sensitive pole markers, user inputs, and the photometric automation module 511. Real-time feedback may include error-checking, lighting and optimization suggestions, a design feasibility review may include.

In certain embodiments, the design module may be able to send proposal generation information create a proposal for a lighting system, including sending the proposal to a printer or to viewing software for proposal dissemination. Information in the generated proposal may include, for example, pricing, product specification, and installation details.

The design module may further be integrated with a customer relation management system. In other embodiments, the design module may be on a mobile device in signal communication with Lighting Layout Application.

The specification module 503 may provide photometric design information, bid specifications, and project documentation. The specification module 503 may run on the same computing device or on a different network signal connected device as the design module.

The specification module 503 may automate lighting system design by providing for lighting pole location based on satellite footage from the photometric module. The satellite footage may be in the form of an image file provided to the specification module 503. A coordinate grid may be provided or layered onto the satellite footage with x and y cartesian coordinates.

The specification module 503 may gather and coordinate calculations from the spill light calculation module 513, including mapping, spill lines, and on-field candela calculations.

A user may be able to select priority metrics for design automation. For example, a user may be able to prioritize result output based on cost, uniformity of lighting, or other metrics for design optimization.

The specification module 503 may provide breaker sizing input based on voltage input and lighting requirements provided by the design automation module.

The specification module 503 may have a specification library 515 including standard and customizable templates. The specification module 503 may be able to create documents to provide full bid specifications in common formats which may be disseminated. Formats may include, for example, PDF, .docx, and CAD formats.

In certain embodiments a specification output module may provide execution and processing of data and may display information for the user or may send information to an output display for the user.

The build module 505 may be able to, for example, generate installation drawings, including design and aiming drawings and pole coordinates. The build module 505 may be able to send design error information to the design module, either automatically based on calculations or from input from a user. The build module 505 may be able to, for example, provide a bill of materials, installation instructions based on the type of poles and light fixtures used, breaker sizing, and pricing information. Pricing may also be broken down into step-by-step segments or into various installation alternative options to help account for cost. In certain embodiments, a build processing module 519 may perform data execution and processing for the build module 505.

The build module 505 may be able to provide networked communication access via the network, internet, cloud storage, or any person.

A user input device (e.g., keyboard, text pad, voice commands, etc.) may be used to enter data and a user output device (e.g., a monitor, printer, etc.) may be used to access data from the Lighting Layout Application and its various modules.

Still referring to FIG. 32, the Lighting Layout Application may have a communication channel 561 between the design module 501 and the specification module 503; a communication channel 563 between the specification module 503 and the build module 505; and a communication channel 565 between the design module 501 and the build module 505. The design module 501 may have a communication channel to an output device 569. The specification module 503 may have a communication channel to an output device 567. The build module 505 may have a communication channel to an output device 571.

In one embodiment a method for light fixture implementation includes receiving a map and luminosity information 701; creating spill lines 703; overlaying a coordinate grid on a map 705; generate light pole locations on the map 707; creating light pole height and light intensity results 709; generating circuit breaker sizing 711; generating a bill of materials 713; generating light pole installation instructions 715; and providing proposal pricing 717.

The present invention may be a system, a method, device, and/or a computer program product at any possible technical detail level of integration. The computer program product may include a computer readable storage medium (or media) having computer readable program instructions thereon for causing a processor to carry out aspects of the present invention.

In some embodiments, aspects of the present invention may take the form of a computer program product, which may be embodied as computer readable medium(s). A computer readable medium may be a tangible storage device/medium having computer readable program code/instructions stored thereon. Example computer readable medium(s) include, but are not limited to, electronic, magnetic, optical, or semiconductor storage devices or systems, or any combination of the foregoing. Example embodiments of a computer readable medium include a hard drive or other non-transitory mass-storage device, an electrical connection having wires, random access memory (RAM), read-only memory (ROM), erasable-programmable read-only memory such as EPROM or flash memory, an optical fiber, a portable computer disk/diskette, an optical storage device, a magnetic storage device, or any combination of the foregoing. The computer readable medium may be readable by a processor, processing unit, or the like, to obtain data (e.g. instructions) from the medium for execution. In a particular example, a computer program product is or includes one or more computer readable media that includes/stores computer readable program code to provide and facilitate one or more aspects described herein.

As noted, program instruction contained or stored in/on a computer readable medium can be obtained and executed by any of various suitable components such as a processor of a computer system to cause the computer system to behave and function in a particular manner. Such program instructions for carrying out operations to perform, achieve, or facilitate aspects described herein may be written in, or compiled from code written in, any desired programming language.

The terms software, application, program code, computer program code, code, computer program product, and executable instructions, are used interchangeably throughout this application. Program code can include one or more program instructions obtained for execution by one or more processors. Computer program instructions may be provided to one or more processors of, e.g., one or more computer systems, to produce a machine, such that the program instructions, when executed by the one or more processors, perform, achieve, or facilitate aspects of the present invention, such as actions or functions described in flowcharts and/or block diagrams described herein. Thus, each block, or combinations of blocks, of the flowchart illustrations and/or block diagrams depicted and described herein can be implemented, in some embodiments, by computer program instructions.

As described above, the present invention may be a system, a device, a method, and/or a computer program associated therewith and is described herein with reference to flowcharts and block diagrams of methods and systems. The flow chart and block diagrams illustrate the architecture, functionality, and operation of possible implementations of systems, methods, and computer programs of the present invention. In some implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It should be understood that each block of the flowcharts and block diagrams can be implemented by computer readable program instructions in software, firmware, or dedicated analog or digital circuits. These computer readable program instructions may be implemented on the processor of a general purpose computer, a special purpose computer, or other programmable data processing apparatus to produce a machine that implements a part or all of any of the blocks in the flowcharts and block diagrams. Each block in the flowchart or block diagrams may represent a module, segment, or portion of instructions, which comprises one or more executable instructions for implementing the specified logical functions. It should also be noted that each block of the block diagrams and flowchart illustrations, or combinations of blocks in the block diagrams and flowcharts, can be implemented by special purpose hardware-based systems that perform the specified functions or acts or carry out combinations of special purpose hardware and computer instructions.

Although various embodiments are described above, these are only examples. For example, computing environments of other architectures can be used to incorporate and use one or more embodiments.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description, but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

What is claimed is:

1. A method for executing instructions in a lighting layout system comprising:
receiving an input layout having:
a project identifier, including a project name, a location, and client information;
field information, including at least one field image, a field type, a background image, a size, and a calculation grid;
field luminosity information;
a field layout associated with the field information, including a quantity of poles, pole locations, a fixture mounting height, a fixture type, a quantity of fixtures, and aiming information;
processing the input layout using the processor;
creating an output having:
a field type;
the quantity of poles and pole locations;
a pole label;
a fixture count per pole;
a total fixture count per type;
a total wattage;
an achieved average light level and uniformity result;
a point-by-point overlay of the field including the pole locations indicated, the fixture schedule, and a results summary for each layout;
an aiming diagram showing the aiming point on the field for each pole; and
a rack diagram showing each fixture and its aiming for each pole; and
displaying the output by the output device.

2. The method for determining the lighting layout of claim 1 wherein the input layout further includes a second calculation grid for non-symmetrical field types.

3. The method for executing instructions in lighting layout system of claim 1, wherein the output further includes adjusted pole locations based on lighting requirements.

4. The method for executing instructions in lighting layout system of claim 1, wherein the output further includes light levels.

5. The method for executing instructions in lighting layout system of claim 1, wherein the output further includes an aiming angle.

6. The method for executing instructions in lighting layout system of claim 1, wherein the output further includes a plurality of aiming angles and field uniformity and target efficiency data associated with each of the plurality of aiming angles.

7. The method for executing instructions in lighting layout system of claim 1, wherein the output further includes adjusting the quantity of poles.

8. The method for executing instructions in lighting layout system of claim 2, wherein the output further includes adjusted pole locations based on lighting requirements for the calculation grid and for the second calculation grid.

9. The method for executing instructions in lighting layout system of claim 1, wherein the output further includes spill lines.

10. The method for executing instructions in lighting layout system of claim 1, further including entering data by the input device to adjust the input layout.

11. The method for executing instructions in lighting layout system of claim 1, further including entering data by the input device to adjust the output.

12. A method for light fixture implementation including:
receiving a map and luminosity information;
creating spill lines;
overlaying a coordinate grid on a map;
generate light pole locations on the map;
creating light pole height and light intensity results;
generating circuit breaker sizing;
generating a bill of materials;
generating light pole installation instructions; and
providing proposal pricing.

13. A lighting layout system for executing instructions comprising:
receiving an input layout having:
a project identifier, including a project name, a location, and client information;
field information, including at least one field image, a field type, a background image, a size, and a calculation grid;
field luminosity information;
a field layout associated with the field information, including a quantity of poles, pole locations, a fixture mounting height, a fixture type, a quantity of fixtures, and aiming information;
processing the input layout using the processor;
creating an output having:
a field type;
the quantity of poles and pole locations;
a pole label;
a fixture count per pole;
a total fixture count per type;
a total wattage;
an achieved average light level and uniformity result;
a point-by-point overlay of the field including the pole locations indicated, the fixture schedule, and a results summary for each layout;
an aiming diagram showing the aiming point on the field for each pole; and
a rack diagram showing each fixture and its aiming for each pole; and
displaying the output by the output device.
